(19) United States
(12) Patent Application Publication
(10) Pub. No.: US 2026/0148888 A1
(43) Pub. Date: May 28, 2026

(54) Semiconductor Device and Method of Making a Balun with an Improved Common-Mode Rejection Ratio

(71) Applicant: JCET STATS ChipPAC Korea Limited, Incheon (KR)

(72) Inventors: JiHyoung Yu, Seoul (KR); Myungki Kim, Incheon (KR); Dongmin Kim, Gyeonggi-do (KR)

(73) Assignee: JCET STATS ChipPAC Korea Limited, Incheon (KR)

(21) Appl. No.: 18/962,190

(22) Filed: Nov. 27, 2024

(51) Int. Cl. H01F 27/28; H01L 23/522; H03H 7/42

(52) U.S. Cl. CPC H01F 27/2804; H03H 7/42; H10W 20/497; H01F 2027/2809

(57) ABSTRACT

An electronic device has a first transformer and a second transformer. A first coil of the first transformer is coupled to a first coil of the second transformer through an interconnection transmission line. A phase-compensation transmission line is coupled to a second coil of the first transformer. The phase-compensation transmission line is configured to match an impedance of the interconnection transmission line.

### FIELD OF THE INVENTION

The present invention relates in general to semiconductor devices and, more particularly, to semiconductor devices and methods of making a balun with an improved common-mode rejection ratio.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices and other electronic devices, especially those that process radio frequency (RF) signals, commonly rely on devices called baluns to convert a signal between balanced and unbalanced form. FIG. 1a shows a balun 10 as a block diagram. Balun 10 has an unbalanced port 12 and a balance port 16. Balanced port 16 includes two balanced outputs 16a and 16b. The general balun concept is that an unbalanced signal input to unbalanced port 12 is output to both balanced ports 16a and 16b. The output signal at balanced port 16b is ideally the exact opposite of the output signal at balanced port 16a. That is, the signals at balanced ports 16a and 16b should have a phase difference of 180-degrees.

One common balun topology uses a pair of transformers 20a and 20b to generate the signals at output ports 16a and 16b, respectively. An RF signal input to port 12 is routed through coil 22a of transformer 20a and coil 22b of transformer 20b in series. Transformer 20a has a second coil 24a that is magnetically coupled to coil 22a to generate a first output signal at balanced port 16a. Transformer 20b has a second coil 24b that is magnetically coupled to coil 22b to generate a second output signal at balanced port 16b. The relationship between coils 22a and 24a in transformer 20a is typically the reverse of the relationship between coils 22b and 24b in transformer 20b, e.g., by flipping the physical coil direction for one of the coils, to reverse the polarity of the output signal at port 16b relative to the output signal at port 16a. Coils 24a and 24b are coupled to a ground circuit node 26 opposite balanced ports 16a and 16b so that the balanced output signals are relative to a common ground.

Transformers 20a and 20b are typically formed as almost identical mirror images of each other to ensure that the signals at output ports 16a and 16b are as nearly identical as possible but with a 180-degree phase difference. However, there will be an additional conductive element or interconnection transmission line 30, e.g., a conductive trace or conductive via, that inevitably has an impedance θ₁ that will cause transformers 20a and 20b to imperfectly mirror each other. The impedance θ₁ will add a phase imbalance between the signals at balanced ports 16a and 16b because the impedance is only applied to the output signal to balanced port 16b and not to the signal to balanced port 16a.

The longer the transmission line 30, the greater the amplitude and phase imbalance between balanced output ports 16a and 16b. The amplitude and phase imbalance at 6 GHz is greater than at the lower frequency of 3.2 GHz, thus narrowing the operating frequency band of balun 10 and worsening the return loss and insertion loss.

FIG. 1b shows graphed plots of balanced signal 40a on balanced output 16a and balanced signal 40b on balanced output 16b. The extra impedance θ₁ that the balanced input signal travels through to reach transformer 20b introduces a phase imbalance so that the balanced signals 40a and 40b are not 180-degrees out of phase as desired. While signal 40a crosses the horizontal axis at time θ, the signal 40b is delayed and does not cross the horizontal axis until time Δ.

Having balanced signals 40a and 40b that do not have a near-exact 180-degree phase difference degrades the capability of noise cancelling inherent in balanced signals. Therefore, a need exists for a balun with an improved common-mode rejection ratio.

### BRIEF DESCRIPTION OF THE DRAWINGS

FIGS. 1a and 1b illustrate a balun in the prior art;

FIGS. 2a and 2b illustrate a balun with improved common-mode rejection ratio;

FIGS. 3a-3f illustrate the improved balun in a low temperature co-fired ceramic embodiment; and

FIG. 4 illustrates a plot of the improvement in CMRR between the prior art balun and the improved balun.

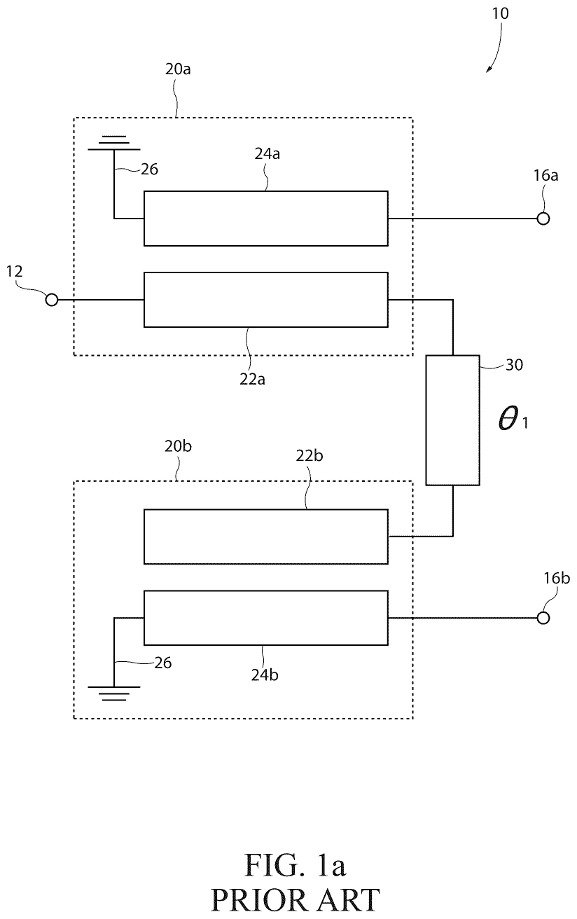

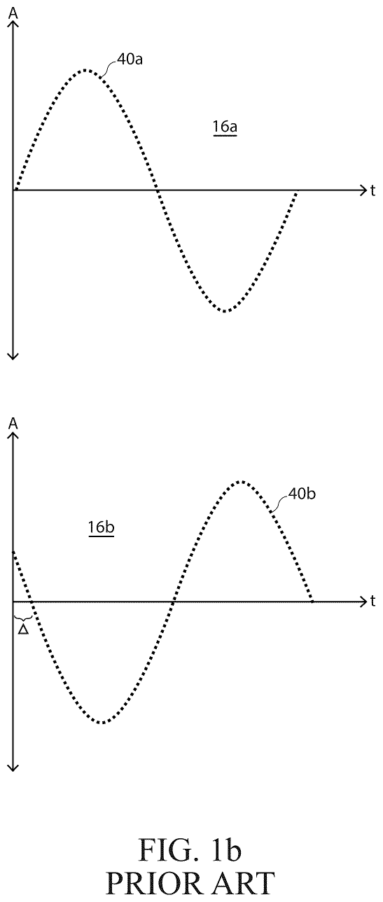

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other.

Relative terms, such as overlying or underlying, are used herein consistently with the orientations of components in the figures. However, end devices can be disposed in any orientation. Relative terms also need to be considered in the context with which they are used, because, e.g., terms like over and under can refer to different directions depending on the orientation of the components being described. While the unbalanced port is discussed herein as an input and the balanced ports are discussed as outputs, baluns are typically bidirectional devices. A balanced signal can also be applied to the balanced ports to output an unbalanced signal in most embodiments.

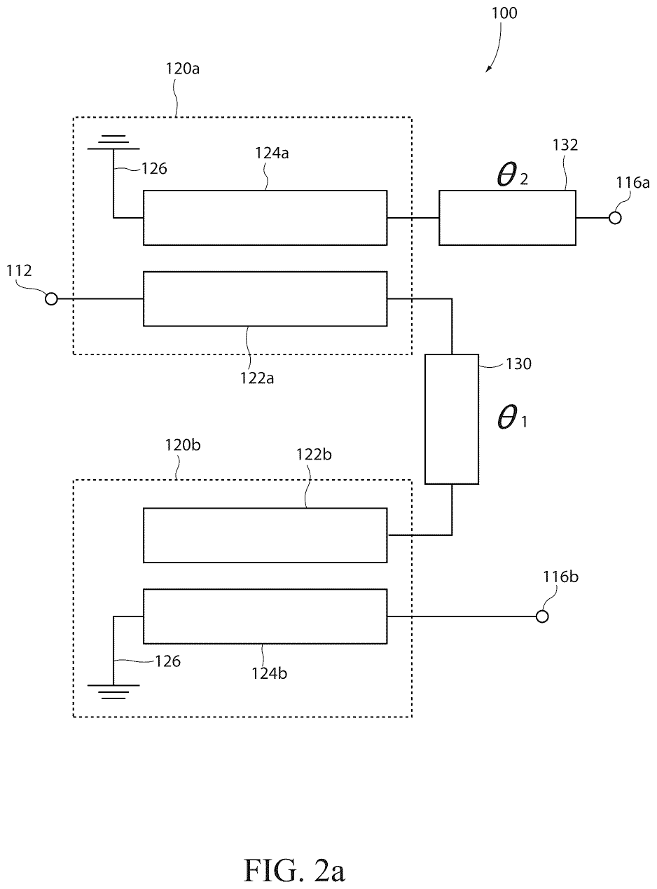

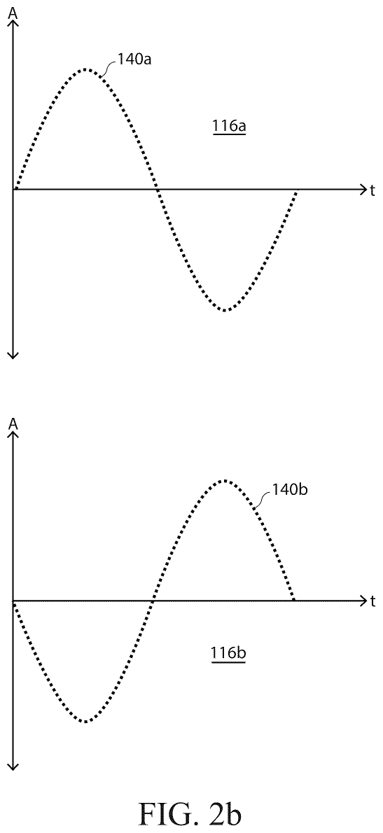

FIGS. 2a and 2b illustrate a balun 100 with an improved common-mode rejection ratio (CMRR) relative to the prior art. FIG. 2a shows balun 100 as a functional block diagram. Balun 100 has an unbalanced port 112 and a balance port 116. Balanced port 116 includes two balanced outputs 116a and 116b. Transformers 120a and 120b are used to generate balanced output signals at output ports 116a and 116b, respectively. An RF signal input to port 112 is routed through coil 122a of transformer 120a and coil 122b of transformer 120b in series.

Transformer 120a has a second coil 124a that is magnetically coupled to coil 122a to generate a first output signal at balanced port 116a. Transformer 120b has a second coil 124b that is magnetically coupled to coil 122b to generate a second output signal at balanced port 116b. The relationship between coils 122a and 124a in transformer 120a is typically the reverse of the relationship between coils 122b and 124b in transformer 120b, e.g., by flipping the physical coil direction for one of the coils, to reverse the polarity of the output signal at port 116b relative to the output signal at port 116a. Coils 124a and 124b are coupled to a ground circuit node 126 opposite balanced ports 116a and 116b so that the balanced output signals are relative to a common ground.

Transformers 120a and 120b are typically formed as almost identical mirror images of each other to ensure that the signals at output ports 116a and 116b are as nearly identical as possible but with a 180-degree phase difference. To counteract the impedance θ₁ of interconnect transmission line 130, an impedance θ₂ is added as part of a conductive element or phase compensation transmission line 132 between coil 124a and balanced output port 116a. Impedance θ₂ is configured to improve the CMRR of balun 100 by compensating for the phase imbalance caused by interconnection transmission line 130 having impedance θ₁. Any physical implementation of balun 100 will include transmission lines from coil 124a to balanced output port 116a and from coil 124b to balanced output port 116b. Phase-compensation transmission line 132 represents an impedance θ₂ in addition to the transmission lines used to interconnect balun 100 to other devices.

The signal path from unbalanced input port 112 to balanced output port 116b goes through coil 122a and interconnection transmission line 130 to coil 122b by electrical coupling, and then to coil 124b by magnetic coupling. The signal path from unbalanced input port 112 to balanced output port 116a goes from coil 122a to coil 124a by magnetic coupling, and then through phase compensation transmission line 132 by electrical coupling. Therefore, the signal paths to both balanced output ports 116a and 116b include a pair of coils 122 and 124, and an additional impedance. The additional impedances θ₁ and θ₂ can be matched so that the overall impedance from unbalanced input port 112 to balanced output port 116a is equal to or approximately equal to the overall impedance from the unbalanced input port to balanced output port 116b.

Phase compensation transmission line 132 adds a common-mode rejection pole within the operating frequency and allows the compensation of phase imbalance to be tunable according to its degree. Return loss and insertion loss are improved at higher frequencies within the operating frequency band, thus offering a wider operating frequency band for balun 100. The CMRR is improved for a better signal-to-noise ration (SNR). The above-listed benefits are provided with no need for a matching network.

Phase compensation transmission line 132 makes the signals at output ports 116a and 116b 180-degrees out-of-phase, i.e., equal or nearly equal amplitudes but opposite or nearly opposite in polarity. Two things being “nearly” equal or “nearly” opposite means that an attempt was made to make the two things equal or opposite, respectively, while ultimately the two things may not be exactly equal or opposite. Approximately and nearly are considered synonymous.

In any case, the value of impedance θ₂ of phase compensation transmission line 132 is configured based on the design of balun 100 and the impedance θ₁ of the selected interconnection transmission line 130 used to connect transformer 120a to transformer 120b. The impedance θ₂ is exactly or nearly exactly the same as impedance θ₁ in some embodiments. In other embodiments, impedance θ₂ can be intentionally different from impedance θ₁ to also compensate for other differences between the two balanced paths, e.g., a time delay for signal transmission between transformers 120a and 120b. The impedance of the two balanced ports 116a and 116b should be the same or approximately the same. Additionally, the characteristic impedance of the coupled lines has even and odd mode characteristic impedances, which should be the same or approximately the same.

FIG. 2b illustrates plots of output signals 140a and 140b on balanced output ports 116a and 116b, respectively, in the ideal case. The balanced output signals 140a and 140b have identical magnitudes and exactly opposite amplitudes A on the vertical axis over time. Phase compensation transmission line 132 eliminates the delay Δ in the prior art second balanced signal 40b relative to balanced signal 40a so that balanced signals 140a and 140b are better matched.

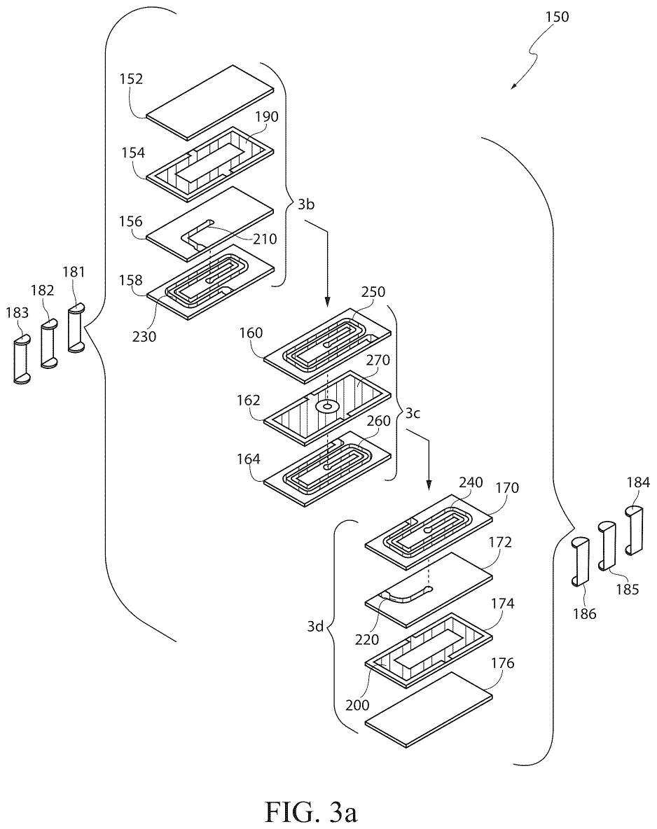

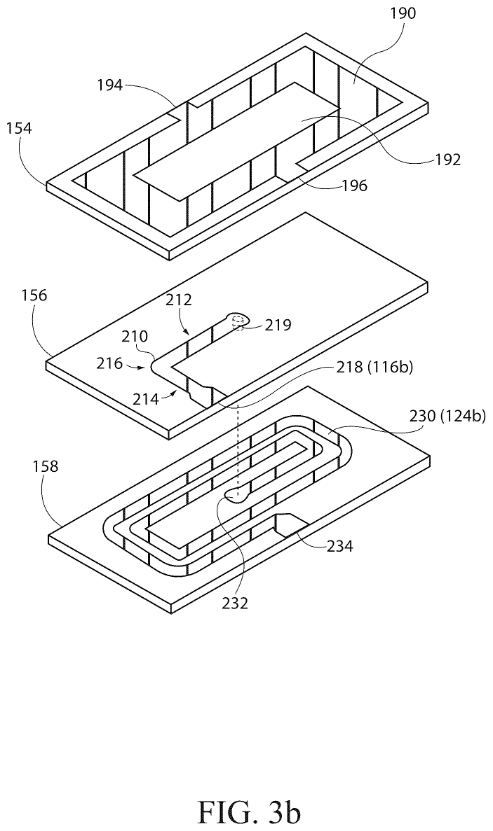

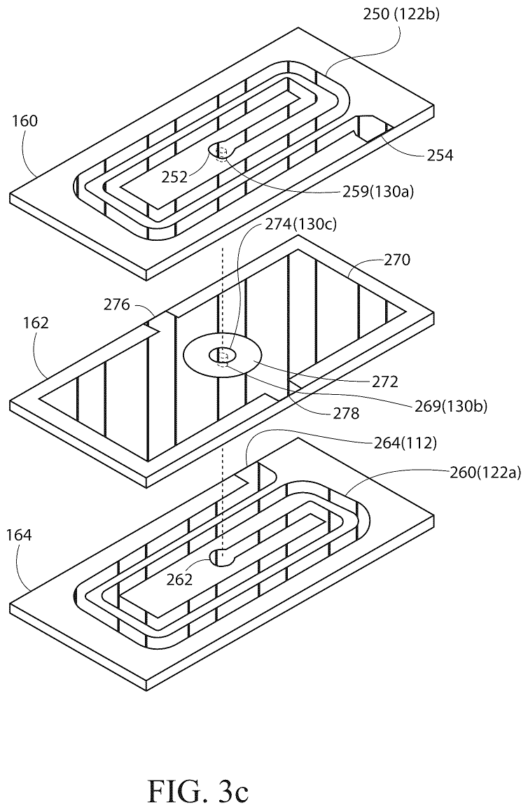

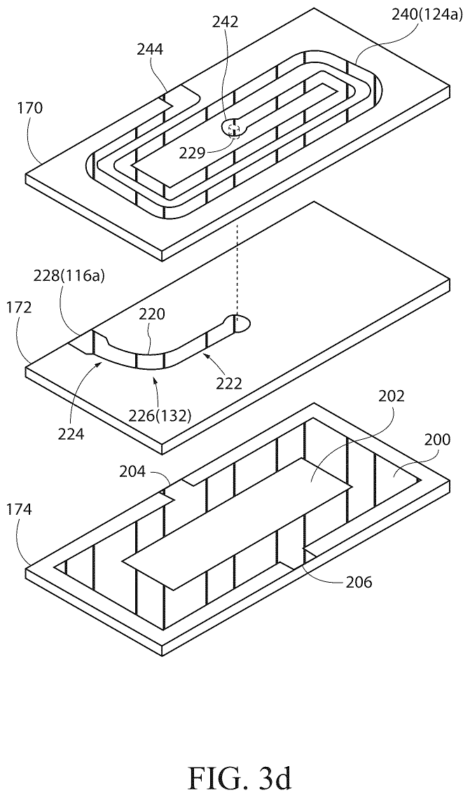

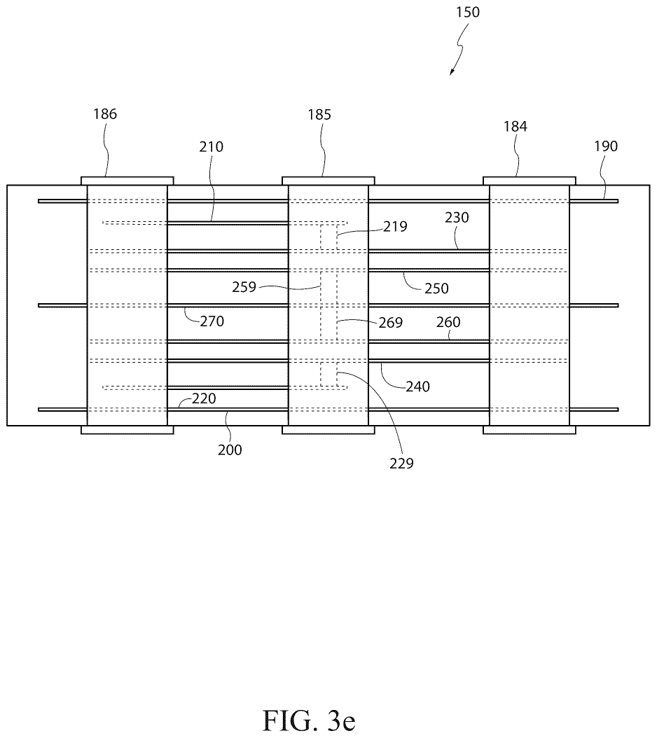

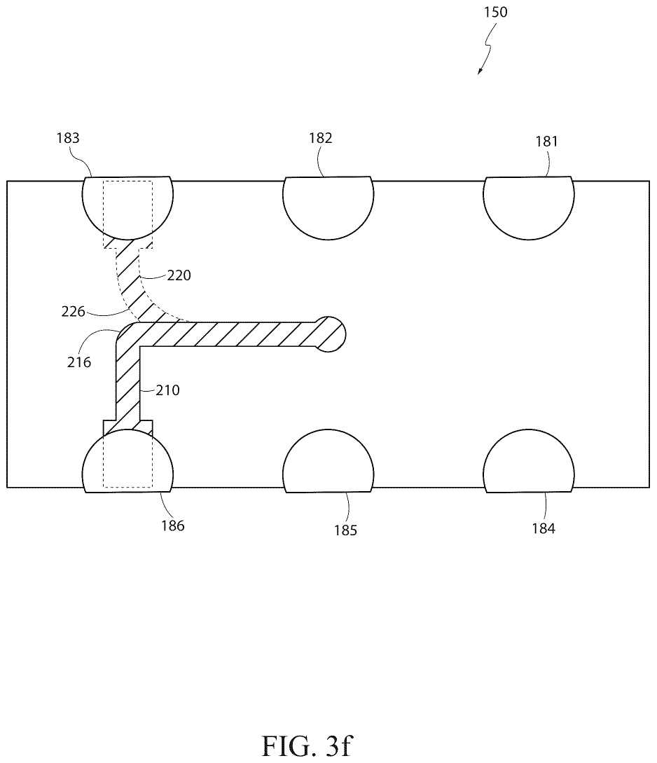

FIGS. 3a-3f illustrate a balun 150 in one embodiment. Balun 150 is a discrete device manufactured using a low-temperature co-fired ceramic (LTCC) manufacturing process according to the block diagram from FIG. 2a. Reference numbers in parenthesis in FIGS. 3b-3d indicate elements from FIG. 2a most closely aligned to or implemented by the referenced element in FIGS. 3b-3d. LTCC devices are formed by forming sheets from a slurry of, e.g., ceramics, organic resin, and a solvent. The slurry is formed into a thin sheet by tape casting, where the slurry is extruded with a resin binder on a moving belt. In other embodiments, any suitable dielectric material is used for the sheets rather than strictly a ceramic material.

The ceramic sheet is cut out of the mold for each device layer, and vias are punched or lasered into the ceramic according to the desired wiring pattern. The vias are filled with a conductive material, and conductive material is precision printed onto each device layer or otherwise deposited and patterned to form the desired conductive layers on each device layer. All of the device layers, each on one piece of the ceramic sheet, are laminated together before sintering or firing all of the device layers at once. Any suitable LTCC or high-temperature co-fired ceramic process is used in other embodiments. The device layers can be formed using any type of semiconductor device substrate or interposer in other embodiments.

Balun 150 is formed of eleven different device layers in a stack: first or top layer 152, second layer 154, third layer 156, fourth layer 158, fifth layer 160, sixth layer 162, seventh layer 164, eighth layer 170, ninth layer 172, tenth layer 174, and eleventh layer or bottom layer 176. In the end device, the device layers are stacked directly on each other in the order illustrated, with fourth layer 158 on top of fifth layer 160 and seventh layer 164 on top of eighth layer 170. FIG. 3b shows device layers 154-158 in greater detail, FIG. 3c shows device layers 160-164 in greater detail, and FIG. 3d shows layers 170-174 in greater detail.

After the device layers are stacked, six terminals or external electrodes 181-186 are mounted or disposed onto the sides of the stacks. Wherever one of the device layers has its conductive layer patterned to extend to the edge of the particular device layer, that conductive layer electrically connects to an adjacent terminal 181-186. The electrical connections to terminals 181-186 can be made by simple physical contact to the side surfaces of the device layers, and thereby the conductive layers formed on the device layers, or a conductive adhesive or solder can be added to the inner surfaces of the terminals to physically attach the terminals as well as improve electrical connection reliability. In the illustrated embodiment, terminal 181 is the unbalanced input-output, while terminals 183 and 186 are the balanced inputs-outputs. Terminals 182 and 185 are connected to ground 126 while terminal 184 is not used.

Top device layer 152 and bottom device layer 176 have no conductive elements and sit on the top and bottom of the device for protection. Second device layer 154 and tenth device layer 174 sit just inside top layer 152 and bottom layer 176, respectively, and have shielding layers formed to limit the exposure of surrounding components to the magnetic and electrical fields generated by balun 150. Conductive layer 190 of device layer 154 is formed as a continuous conductive path around an opening 192 in the middle of the conductive layer. Conductive layer 200 of device layer 174 is formed as a continuous conductive path around an opening 202 in the middle of the conductive layer.

Conductive layer 190 extends to the outer edge of device layer 154 at points 194 and 196 near the center of the device layer laterally to electrically contact terminals 182 and 185 in the final device. Conductive layer 200 extends to the outer edge of device layer 174 at points 204 and 206 near the center of the device layer edge to electrically contact terminals 182 and 185 in the final device. Terminals 182 and 185 are designated as ground circuit nodes, thereby coupling conductive layers 190 and 200 to ground 126 to improve shielding performance against the outside electromagnetic environment. The openings 192 and 202 are configured to modify the impedance of the adjacent striplines.

Device layer 156 sits under device layer 154 and includes a conductive layer 210 used as a transmission line. Conductive layer 210 includes a first linear portion 212, a second linear portion 214, and a right angle 216 connecting linear portions 212 and 214. Conductive layer 210 is a transmission line that extends from point 218 at the edge of device layer 156 to a conductive via 219 formed through the center of the device layer. Point 218 will be directly under terminal 186 in the final device to operate as balanced output 116b from the block diagram in FIG. 2a. Conductive via 219 extends through device layer 156 to connect conductive layer 210 to the underlying device layer 158 when the device layers are laid on top of each other.

Device layer 172 sits on device layer 174 and includes a conductive layer 220 used as a transmission line. Conductive layer 220 includes a first linear portion 222, a second linear portion 224, and a radiused corner 226 connecting the first linear portion and second linear portion. In other embodiments, radiused corner 226 extends entirely to one or both ends of the transmission line, eliminating one or both linear portions 222 and 224. Conductive layer 220 is a transmission line that extends from point 228 at the edge of device layer 172 to the center of the device layer. The overlying device layer 170 includes a conductive via 229 at the center of the device layer to electrically connect to conductive layer 220 when the device layers are stacked. Point 228 will be directly under terminal 183 in the final device to operate as balanced output 116a from the block diagram of FIG. 2a.

The transmission line of conductive layer 210 to balanced output 116b forms a right angle, while the transmission line of conductive layer 220 to balanced output 116a has a radiused corner. The modification of the shape of conductive layer 220 relative to conductive layer 210 operates as phase-compensation transmission line 132 from the block diagram of FIG. 2a. Radiused corner 226 itself can be considered as phase-compensation transmission line 132, or the phase-compensation transmission line 132 can be considered as the difference between right-angle corner 216 and radiused corner 226.

Shortening the transmission line to balanced output 116a relative to the transmission line to balanced output 116b modifies impedance to compensate for interconnection transmission line 130. In one embodiment, a difference in length between conductive layer 210 and conductive layer 220 is configured to equal a length of interconnection transmission line 130. For instance, if interconnection transmission line 130 is a conductive via with a length of 100 μm, then the radiused corner 226 should be configured to reduce the overall length of the conductive layer 220 transmission line by the same 100 μm relative to the transmission line of conductive layer 210. Conductive layer 220 can also be shortened, or conductive layer 210 lengthened, by other suitable means, such as multiple discrete angles, by changing the angles of linear portions 222 and 224, or by moving vias 219 or 229. The lengths of the balanced conductive traces 210 and 220 are differentiated in order to compensate for the phase imbalance caused by interconnection transmission line 130. The relative lengths of conductive traces 210 and 220 are differentiated to minimize or approximately minimize return loss.

Device layer 158 sits under device layer 156 and includes a conductive layer 230 shaped as a coil to act as coil 124b from the block diagram in FIG. 2a. Conductive layer 230 wraps in two complete coils from point 232 at the center of device layer 158 to point 234 at the outer edge of the device layer. Point 234 of conductive layer 230 is positioned laterally at the center of the edge of device layer 158 to be positioned under terminal 185 in the final device, thereby connecting coil 124b to ground 126 as shown in the block diagram on FIG. 2a. In combination, conductive layer 230, conductive via 219, and conductive layer 210 form a coil 124b and transmission line from ground 126 at terminal 185 to a balanced output 116b at terminal 186. Device layers 156 and 158 are electrically isolated from other device layers, but magnetically coupled to an underlying coil.

Device layer 170 sits on device layer 172 and includes a conductive layer 240 shaped as a coil to act as coil 124a from the block diagram in FIG. 2a. Conductive layer 240 wraps in two complete coils from point 242 at the center of device layer 170 to point 244 at the outer edge of the device layer. Conductive layer 240 coils in the opposite direction relative to conductive layer 230 to reverse coils 124a and 124b, thereby reversing the polarity of balanced outputs 116a and 116b. Point 244 of conductive layer 240 is positioned laterally at the center of the edge of device layer 170 to be positioned under terminal 182 in the final device, thereby connecting coil 124a to ground 126 as shown in the block diagram on FIG. 2a. Point 242 of conductive layer 240 has a contact pad formed on conductive via 229. When device layers 170 and 172 are stacked, conductive layer 240 is electrically connected to conductive layer 220 through conductive via 229. In combination, conductive layer 240, conductive via 229, and conductive layer 220 form a coil 124a and transmission line from ground 126 at terminal 182 to a balanced output 116a at terminal 183. Device layers 170 and 172 are electrically isolated from other device layers, but magnetically coupled to an overlying coil.

Device layer 160 sits under device layer 158 and has a conductive layer 250 shaped as a coil to act as coil 122b from the block diagram in FIG. 2a. Conductive layer 250 wraps in just over two complete coils from point 252 in the center of device layer 160 to point 254 at an outer edge of the device layer. Coil 122b of conductive layer 250 is magnetically coupled to coil 124b of conductive layer 230 to form transformer 120b. Point 254 at the edge of device layer 160 sits under terminal 184 in the assembled end device. Conductive layer 250 extends to terminal 184 in order to balance coil 122a and 122b, but terminal 184 is not intended to be used in the end device. In other embodiments, conductive layer 250 does not extend to terminal 184. A conductive via 259 is formed through device layer 160 under a contact pad of conductive layer 250 at point 252. Conductive via 259 is one part of the overall conductive structure that connects coils 122a and 122b, i.e., interconnection transmission line 130, and is therefore labelled as being interconnection transmission line 130a.

Device layer 164 sits over device layer 170 and has a conductive layer 260 coiled to act as coil 122a from the block diagram in FIG. 2a. Conductive layer 260 wraps in just over two complete coils from point 262 in the center of device layer 164 to point 264 at an outer edge of the device layer. Coil 122a of conductive layer 260 is magnetically coupled to coil 124a of conductive layer 240 to form transformer 120a. Point 264 sits under, and is electrically connected to, terminal 181 in the assembled device, to operate as the unbalanced input 112. A conductive via 269 is formed through the center of device layer 162 to complete the electrical connection between device layer 160 and device layer 164. Conductive via 269 in combination with conductive via 259 form interconnection transmission line 130. Therefore, conductive via 269 is labelled as being interconnection transmission line 130b.

Device layer 162 sits between device layers 160 and 164. Device layer 162 includes a conductive layer 270 that covers a majority of the footprint of the device layer as a shielding layer between transformers 120a and 120b. Conductive layer 270 has an opening 272 between the shielding layer portion and a contact pad 274 formed as part of the conductive layer on conductive via 269. Contact pad 274 of conductive layer 270 is electrically isolated from the ground plane of conductive layer 270 by opening 272. Contact pad 274 sits vertically between conductive vias 259 and 269 as a minor portion of interconnection transmission line 130 and is therefore labelled as corresponding to interconnection transmission line 130c. Conductive via 259, contact pad 274, and conductive via 269 in combination electrically connect coil 122b of conductive layer 250 to coil 122a of conductive layer 260 to operate as interconnection transmission line 130. The ground plane portion of conductive layer 270 extends to the edges of device layer 162 at points 276 and 278 to electrically connect the ground plane to ground 126 via terminals 182 and 185.

FIG. 3e shows a side view of balun 150 with all of the device layers stacked and terminals 181-186 added. The lines between device layers are not illustrated to better highlight the structure of conductive elements within balun 150. In the middle of balun 150 vertically, conductive layers 250 and 260 are coupled in series by conductive vias 259 and 269. No conductive element extends up from conductive layer 250 or down from conductive layer 260. Instead, conductive layer 230 forms transformer 120b by being magnetically coupled to conductive layer 250 and conductive layer 240 forms transformer 120a by being magnetically coupled to conductive layer 240. Conductive layers 210 and 220 route the balanced signals to output terminals 186 and 183.

Device layers are formed to different thicknesses in some embodiments to adjust magnetic coupling and other characteristics of balun 150. The differing thicknesses can be achieved by forming the initial sheets of ceramic material to varying thicknesses. In other embodiments, one or more blank or empty device layers can be added to widen the distance between two adjacent conductive layers. The empty device layers have conductive vias formed through them as necessary to maintain the electrical connections of conductive vias 229, 269, 259, and 219.

FIG. 3f shows a plan view comparing the footprints and conductive paths of conductive layer 210 and conductive layer 220. The broader radiused corner 226 is contrasted against the sharp right-angle corner 216. The different shape of conductive layer 220 compared to conductive layer 210 modifies the impedance of conductive layer 220 to form a phase-compensation transmission line 132.

Balun 150 with a phase-compensation transmission line 132 implemented by modifying the shape of conductive layer 220 relative to conductive layer 210 improves the CMRR of the balun by compensating for the phase imbalance caused by the interconnection transmission line 130 implemented by conductive via 259, contact pad 274, and conductive via 269. The operating frequency band is increased while return loss and insertion loss are reduced. Implementing phase-compensation transmission line 132 by reshaping existing conductive layers provides for a miniaturized multi-layer structure that does not require external circuits.

Phase-compensation transmission line 132 improves CMRR for balun 150. Improving CMRR helps balun 150 effectively reject common-mode signals, thus maintaining integrity of the desired differential signals. Noise introduced from external sources is greatly reduced. Balun 150 having a high CMRR contributes to stable operation in varying environmental conditions. A higher CMRR provides better isolation between input and output, which reduces crosstalk and ensures that signals from different paths do not interfere with each other. Moreover, many communication standards require specific performance metrics, including CMRR. Meeting relevant standards is essential for regulatory compliance and product acceptance in the marketplace.

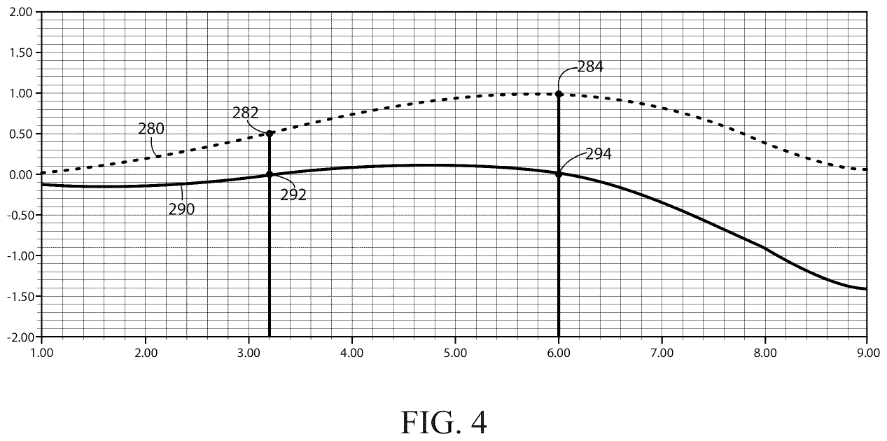

FIG. 4 illustrates the improvements achievable by adding phase-compensation transmission line 132. FIG. 4 plots frequency in gigahertz (GHz) on the horizontal axis and the phase difference in degrees between balanced outputs 116a and 116b on the vertical axis. Plot 280 on the graph illustrates the phase imbalance for balanced outputs 16a and 16b in the prior art in one embodiment. The range of 3.2 GHz to 6.0 GHz is a common operating range for baluns, so those frequencies will be specifically discussed. Plot 280 crosses the 3.2 GHz vertical line at point 282, indicating a phase imbalance of 0.52 degrees. CMRR worsens at higher frequencies, and plot 280 reaches 6.0 GHz at point 284 with a phase imbalance of 0.99 degrees.

Plot 290 in FIG. 4 is a plot of phase imbalance of balanced ports 116a and 116b in balun 150 with phase-compensation transmission line 132. Line 290 crosses the 3.2 GHz vertical line at point 292 and the 6.0 GHz vertical line at point 294, both of which have a value of 0.01 degrees. The phase imbalance stays near zero for the entire range between 3.2 GHz and 6.0 GHz for line 290, providing a much wider operating frequency range than the prior art. Phase-compensation transmission line 132 effectively compensates for the phase error of interconnect transmission line 130, which is commonly used in a multi-layer LTCC balun.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making an electronic device, comprising:
providing a first transformer;
providing a second transformer;
coupling a first coil of the first transformer to a first coil of the second transformer through an interconnection transmission line; and
coupling a phase-compensation transmission line to a second coil of the first transformer.

2. The method of claim 1, further including forming the phase-compensation transmission line to match an impedance of the interconnection transmission line.

3. The method of claim 1, further including:
providing a first transmission line extending from the second coil of the first transformer; and
providing a second transmission line extending from a second coil of the second transformer.

4. The method of claim 3, further including forming the phase-compensation transmission line by modifying a shape of the first transmission line relative to the second transmission line.

5. The method of claim 4, wherein the first transmission line includes a radiused corner and the second transmission line includes a right-angle corner.

6. The method of claim 3, further including:
forming the first coil of the first transformer on a first device layer of a low-temperature co-fired ceramics (LTCC) device;
forming the second coil of the first transformer on a second device layer of the LTCC device;
forming the first coil of the second transformer on a third device layer of the LTCC device;
forming the second coil of the second transformer on a fourth device layer of the LTCC device;
forming the first transmission line on a fifth device layer of the LTCC device; and
forming the second transmission line on a sixth device layer of the LTCC device.

7. A method of making an electronic device, comprising:
providing a first transformer;
providing a second transformer;
coupling the first transformer to the second transformer through an interconnection transmission line; and
coupling a phase-compensation transmission line to the first transformer.

8. The method of claim 7, further including forming the phase-compensation transmission line to match an impedance of the interconnection transmission line.

9. The method of claim 7, further including:
providing a first transmission line extending from the first transformer opposite the second transformer; and
providing a second transmission line extending from the second transformer opposite the first transformer.

10. The method of claim 9, further including forming the phase-compensation transmission line by modifying a shape of the first transmission line relative to the second transmission line.

11. The method of claim 10, wherein the first transmission line includes a radiused corner and the second transmission line includes a right-angle corner.

12. The method of claim 9, further including:
forming the first transmission line on a first device layer of a low-temperature co-fired ceramics (LTCC) device; and
forming the second transmission line on a second device layer of the LTCC device.

13. The method of claim 12, wherein the first transformer and second transformer are positioned between the first device layer and second device layer.

14. An electronic device, comprising:
a first transformer;
a second transformer;
an interconnection transmission line, wherein a first coil of the first transformer is coupled to a first coil of the second transformer through the interconnection transmission line; and
a phase-compensation transmission line coupled to a second coil of the first transformer.

15. The electronic device of claim 14, wherein an impedance of the phase-compensation transmission line matches an impedance of the interconnection transmission line.

16. The electronic device of claim 14, further including:
a first transmission line extending from the second coil of the first transformer; and
a second transmission line extending from a second coil of the second transformer.

17. The electronic device of claim 16, wherein the phase-compensation transmission line includes a shape of the first transmission line being different relative to the second transmission line.

18. The electronic device of claim 17, wherein the first transmission line includes a radiused corner and the second transmission line includes a right-angle corner.

19. The electronic device of claim 16, further including:
a first device layer of a low-temperature co-fired ceramics (LTCC) device including the first coil of the first transformer;
a second device layer of the LTCC device including the second coil of the first transformer;
a third device layer of the LTCC device including the first coil of the second transformer;
a fourth device layer of the LTCC device including the second coil of the second transformer;
a fifth device layer of the LTCC device including the first transmission line; and
a sixth device layer of the LTCC device including the second transmission line.

20. An electronic device, comprising:
a first transformer;
a second transformer;
an interconnection transmission line coupling the first transformer to the second transformer; and
a phase-compensation transmission line coupled to the first transformer.

21. The electronic device of claim 20, wherein an impedance of the phase-compensation transmission line matches an impedance of the interconnection transmission line.

22. The electronic device of claim 20, further including:
a first transmission line extending from the first transformer; and
a second transmission line extending from the second transformer.

23. The electronic device of claim 22, wherein the phase-compensation transmission line includes a shape of the first transmission line being different relative to the second transmission line.

24. The electronic device of claim 23, wherein the first transmission line includes a radiused corner and the second transmission line includes a right-angle corner.

25. The electronic device of claim 22, further including:
a first device layer of a low-temperature co-fired ceramics (LTCC) device including the first transmission line; and
a second device layer of the LTCC device including the second transmission line.
